(19) United States
(12) Patent Application Publication
(10) Pub. No.: US 2026/0371648 A1
(43) Pub. Date: Nov. 19, 2026

(54) SEMICONDUCTOR DEVICE AND METHOD FOR FORMING THE SAME

(71) Applicant: TAIWAN SEMICONDUCTOR MANUFACTURING COMPANY LTD., HSINCHU (TW)

(72) Inventors: YUN-FENG KAO, NEW TAIPEI CITY (TW); MING-YEN CHUANG, HSINCHU CITY (TW); HSIAO-HUA HUNG, HSINCHU CITY (TW); TSUNG-HAN WU, NEW TAIPEI CITY (TW); CHIH-YU CHANG, NEW TAIPEI CITY (TW); KATHERINE H. CHIANG, NEW TAIPEI CITY (TW)

(21) Appl. No.: 19/212,560

(22) Filed: May 19, 2025

(51) Int. Cl. H10D 30/67; H10D 30/01

(52) U.S. Cl. CPC H10D 30/6728; H10D 30/0318; H10D 30/6755; H10D 30/6757

(57) ABSTRACT

A semiconductor device includes a gate structure, a channel layer over the gate structure, a gate dielectric layer between the gate structure and the channel layer, and a source structure and a drain structure over the gate structure. A height of the source structure is different from a height of the drain structure. The gate structure has a first surface facing the source structure and the drain structure, and a second surface opposite to the first surface. A width of the first surface is greater than a width of the second surface.

### BACKGROUND

Active devices, such as transistors made from oxide semiconductor (OS) materials represent an advancement in back-end-of-line (BEOL) integration in semiconductor manufacturing, due to low-temperature processing capability of such transistors. This feature is essential for preserving the integrity of devices fabricated in front-end-of-line (FEOL) and middle-end-of-line (MEOL) stages, allowing for the fabrication of transistors in a BEOL structure without risking damage to underlying structures. As the semiconductor industry aims to enhance areal density of integrated circuits, ongoing miniaturization of individual transistors is beginning to plateau. By moving the fabrication of the active devices (i.e., transistors) from the FEOL stage to the BEOL stage, manufacturers can optimize chip area and introduce additional functionalities without compromising existing device layers. Therefore, integration of transistors in BEOL structures offers a strategic opportunity to improve device density while ensuring performance and reliability of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor device according to aspects of the present disclosure in one or more embodiments.

FIG. 2 is a schematic cross-sectional view of a semiconductor device according to aspects of the present disclosure in one or more embodiments.

FIG. 3 is a schematic cross-sectional view of a semiconductor device according to aspects of the present disclosure in one or more embodiments.

FIG. 4 is a schematic cross-sectional view of a semiconductor structure including a semiconductor device according to aspects of the present disclosure in one or more embodiments.

FIG. 5 is a schematic cross-sectional view of a semiconductor structure including a semiconductor device according to aspects of the present disclosure in one or more embodiments.

FIG. 6 is a flowchart representing a method for forming a semiconductor device according to aspects of the present disclosure.

FIGS. 7A to 7I are schematic drawings of a semiconductor device at various fabrication stages constructed according to aspects of the present disclosure in one or more embodiments.

FIG. 8 is a flowchart representing a method for forming a semiconductor device according to aspects of the present disclosure.

FIGS. 9A to 9J are schematic drawings of a semiconductor device at various fabrication stages constructed according to aspects of the present disclosure in one or more embodiments.

FIGS. 10A to 10D are schematic drawings of a semiconductor structure at various fabrication stages constructed according to aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Transistors having a vertical channel may be integrated in a BEOL interconnect structure in order to support improvement in chips such as logic chips employing magnetoresistive random-access memory (MRAM) devices, resistive random-access memory (RRAM) devices, phase-change random-access memory (PCRAM) devices, etc. In some embodiments, the transistor includes a channel pillar vertically disposed between a source structure and a drain structure, and laterally surrounded by a gate structure. In some comparative approaches, it has been found that when a dimension of the source/drain structures is increased in order to reduce resistance, a gate-to-drain short issue may raise. In some alternative approaches, when a dimension of the channel pillar is increased to mitigate the gate-to-drain issue, a channel void issue may be raise.

The present disclosure therefore provides a semiconductor device and a method for forming the same. In some embodiments, the semiconductor device includes a bone-shaped channel pillar that helps to mitigate both the gate-to-drain short issue and the channel void issue by: (1) having wide portions at two opposite ends that are proximal to the source structure and the drain structure, thereby mitigating the gate-to-drain issue; and (2) having a narrow portion between the two wide portions, thereby mitigating the channel void issue.

While the present disclosure discusses aspects of methods of forming a semiconductor device in the context of a BEOL process or a subsequent MEOL process, such as a FinFET formation process in FEOL processes, other embodiments may utilize aspects of this disclosure with other semiconductor fabrication processes.

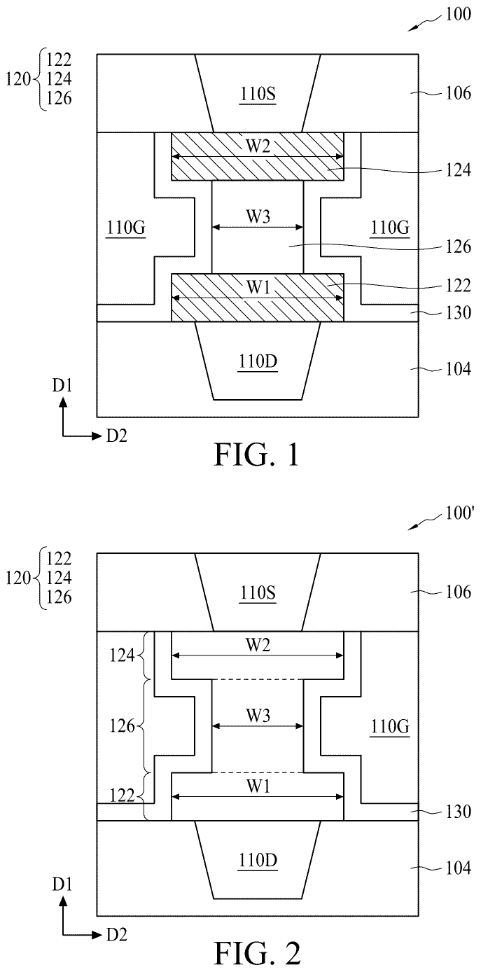

Please refer to FIGS. 1 to 3, wherein each of FIGS. 1 to 3 is a schematic cross-sectional view of a semiconductor device 100, 100′ or 100″ according to aspects of the present disclosure in one of more embodiments. Elements that are same in the embodiments shown in FIGS. 1 to 3 are depicted by same numerals. In some embodiments, elements that are same in the embodiments may have same parameters (e.g., depths or width), but the disclosure is not limited thereto.

In some embodiments, each of the semiconductor devices 100, 100′ and 100″ may be formed over a substrate (not shown). In some embodiments, the substrate (not shown) may be any type of semiconductor body (including, for example, a semiconductor body formed of silicon (Si), silicon germanium (SiGe), silicon-on-insulator (SOI), or like), such as a semiconductor wafer and/or one or more dies on a wafer, as well as a semiconductor body formed of any other type of semiconductor and/or epitaxial layers, suitable for such application.

In some embodiments, the substrate can include FEOL devices and can be a portion of an IC chip, a system-on-chip (SoC), or a portion of a SoC. In some embodiments, the substrate can be a substrate accommodating FEOL devices such as microprocessors, memories, and/or other IC devices. In some embodiments, the substrate can include various passive and active microelectronic devices, such as resistors, capacitors, inductors, diodes, p-type field-effect transistors (PFETs), n-type field-effect transistors (NFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, other suitable components, or combinations thereof. The transistors may be planar transistors or multi-gate transistors, such as fin-type FETs (FinFETs).

In some embodiments, a layer of a MEOL interconnect structure (not shown) can be formed over the substrate. The layer of the MEOL interconnect structure includes a plurality of connecting vias (not shown) disposed in an inter-layer dielectric (ILD) layer (not shown). The connecting vias are coupled to the FEOL devices. In some embodiments, the connecting vias can include a via-to-gate (VG), which generally refers to contact with a gate structure. In other embodiments, the connecting via can include a via-to-drain (VD), which generally refers to contact with a source/drain region. Accordingly, the FEOL devices can be electrically connected to a BEOL interconnect structure through a layer of the MEOL interconnect structure.

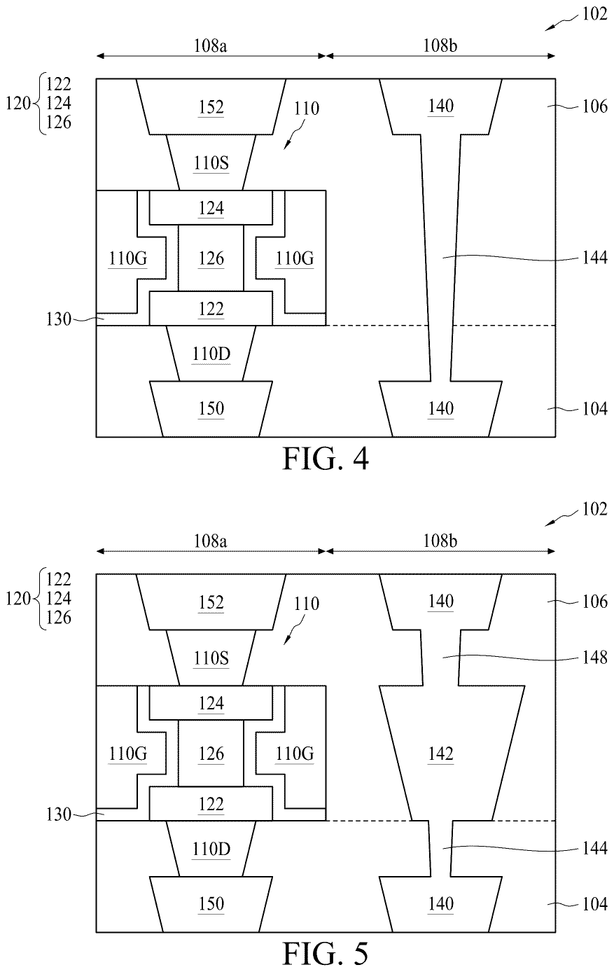

In some embodiments, a BEOL interconnect structure 102 (shown in FIGS. 4 and 5) is formed over the substrate and is electrically connected to the FEOL devices over the substrate. In some embodiments, the BEOL interconnect structure 102 can include a plurality of metallization layers referred to, in ascending order, as the zeroth metallization layer M₀, the first metallization layer M₁, the (N−1)th metallization layer Mₙ₋₁, the Nth metallization layer Mₙ, and the (N+1)th metallization layer Mₙ₊₁, and a plurality of connecting vias referred to as the zeroth connecting via V₀, the first connecting via V₁, and the Nth connecting via Vₙ, wherein n is a positive integer. The (N−1)th metallization layer Mₙ₋₁ and the Nth metallization layer Mₙ can be electrically connected by the Nth connecting via Vₙ. Further, the metallization layer Mₙ and the connecting via Vₙ can be formed in an inter-metal dielectric layer IMDₙ, which provides mechanical support and electrical isolation for the metallization layer Mₙ and the connecting via Vₙ.

In some embodiments, each of the semiconductor devices 100, 100′ and 100″ is disposed in the BEOL interconnect structure 102. For example but not limited thereto, the semiconductor device 100, 100′ or 100″ is disposed in dielectric structures 104 and 106 over the Nth metallization layer Mₙ. In some embodiments, the semiconductor device 100, 100′ or 100″ may be electrically connected to the Nth metallization layer Mₙ and/or the (N+1)th metallization layer Mₙ₊₁, but the disclosure is not limited thereto.

Each of the semiconductor devices 100, 100′ and 100″ includes a drain structure 110D disposed in the dielectric structure 104, and a source structure 110S disposed in the dielectric structure 106. Source/drain region(s)/structures may refer to a source or a drain, individually or collectively dependent upon the context. As shown in FIGS. 1 to 3, the drain structure 110D and the source structure 110S are arranged in a first direction D1 (i.e., a y direction). In some embodiments, each of the source structure 110S and the drain structure 110D includes metallic materials, such as silver (Ag), aluminum (Al), copper (Cu), nickel (Ni), platinum (Pt), ruthenium (Ru), palladium (Pd), tungsten (W), gold (Au), other suitable metallic materials, or alloys thereof, but the disclosure is not limited thereto. In some embodiments, each of the source structure 110S and the drain structure 110D includes metal compounds such as titanium nitride (TiN), tantalum nitride (TaN), metal silicide, or a combination thereof, but the disclosure is not limited thereto. In still other embodiments, each of the source structure 110S and the drain structure 110D includes semiconductor materials, such as polycrystalline silicon, or doped semiconductor materials, such as doped silicon, but the disclosure is not limited thereto. In some embodiments, the source structure 110S and the drain structure 110D include a same material. In some alternative embodiments, the source structure 110S and the drain structure 110D include different materials.

Referring to FIGS. 1 to 3, each of the semiconductor devices 100, 100′ and 100″ includes a channel pillar 120 disposed between the source structure 110S and the drain structure 110D in the first direction D1. In some embodiments, the channel pillar 120 includes a first portion 122 coupled to the drain structure 110D, a second portion 124 coupled to the source structure 110S, and a third portion 126 disposed between the first portion 122 and the second portion 124. Further, a width W3 of the third portion 126 is less than a width W1 of the first portion 122, and less than a width W2 of the second portion 124. The width W1 of the first portion 122 and the width of the second portion 124 may be equal. However, in some embodiments, the width W1 of the first portion 122 may be different from the width W2 of the second portion 124. For example, the width W1 of the first portion 122 may be greater than the width W2 of the second portion 124. The width W1 of the first portion 122 of the channel pillar 120 may be equal to or greater than a width of the drain structure 110D. For example, at an interface between the first portion 122 and the drain structure 110D, the width W1 of the first portion 122 may be equal to or greater than as the width of the drain structure 110D, but the disclosure is not limited thereto. The width W2 of the second portion 124 of the channel pillar 120 may be equal to or greater than the width of the source structure 110S. For example, at an interface between the second portion 124 and the source structure 120S, the width W2 of the second portion 124 is greater than the width of the source structure 120S, but the disclosure is not limited thereto.

Still referring to FIGS. 1 to 3, the width W1 of the first portion 122 and/or the width W2 of the second portion 124 may be increased depending on various product designs such that a distance between the gate structure 110G and the drain structure 110D, and/or a distance between the gate structure 110G and the source structure 110S, are increased. Accordingly, a gate-to-drain short issue is mitigated by the first and second portions 122 and 124. In some embodiments, a ratio of the width W1 of the first portion 122 to the width W3 of the third portion 126 may be greater than 3 in order to mitigate the gate-to-drain short issue and the channel void issue. A ratio of the width W2 of the second portion 124 to the width W3 of the third portion 126 may also be greater than 3 in order to mitigate the gate-to-drain short issue and the channel void issue.

In some embodiments, a ratio of a thickness of the third portion 124 to a thickness of the first portion 122 is greater than 10, and a ratio of the thickness of the third portion 126 to a thickness of the second portion 124 is also greater than 10. In some comparative approaches, when such ratios are less than 10, such device may suffer from loss of channel length, thus degrading a performance of the device.

Each of the semiconductor devices 100, 100′ and 100″ includes the gate structure 110G surrounding the channel pillar 120 in a second direction D2 (i.e., an x direction) different from the first direction D1, and a gate dielectric layer 130 between the gate structure 110G and the channel pillar 120 in the second direction D2. The gate structure 110G may include a conductive material. In some embodiments, the gate structure 110G includes metallic materials, such as silver, aluminum, copper, nickel, platinum, ruthenium, palladium, tungsten, gold, other suitable metallic materials, or alloys thereof, but the disclosure is not limited thereto. In some embodiments, the gate structure 110G includes metal compounds, such as, titanium nitride, tantalum nitride, metal silicide, or combinations thereof, but the disclosure is not limited thereto. In still other embodiments, the gate structure 110G includes semiconductor materials, such as polycrystalline silicon, or doped semiconductor materials, such as doped silicon, but the disclosure is not limited thereto. In some embodiments, the gate structure 110G may include a material same as a material of the source structure 110S and the drain structure 110D. In some alternative embodiments, the gate structure 110G may include a material different from that of the source structure 110S and that of the drain structure 110D.

Each of the semiconductor devices 100, 100′ and 100″ includes the gate dielectric layer 130 disposed between the channel pillar 120 and the gate structure 110G. The gate dielectric layer 130 may include any suitable dielectric material such as silicon oxide (SiO₂), or the like, or a high-k dielectric material such as silicon nitride (SiN₄), hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (Hf_{0.5}Zr_{0.5}O₂), tantalum oxide (Ta₂O₅), aluminum oxide (Al₂O₃), hafnium dioxide-alumina (HfO₂—Al₂O₃), zirconium oxide (ZrO₂), zirconium silicate, zirconium aluminate, zirconium oxide, tantalum oxide (TaO), or the like. Other suitable dielectric materials may also be within the contemplated scope of the disclosure. As shown in FIGS. 1 to 3, the gate dielectric layer 130 is disposed between sidewalls of the channel pillar 120 and the gate structure 110G, and also disposed between the dielectric structure 104 and the gate structure 110G.

Referring back to FIG. 1, in some embodiments, the channel pillar 120 includes an oxide semiconductor material (such as indium gallium zinc oxide (InGaZnO, IGZO), tungsten-doped indium oxide (InWO), indium zinc oxide (InZnO), indium tin oxide (InSnO), indium tungsten oxide (InWO), gallium oxide (GaOx), indium oxide (InOx) or the like), doped zinc oxide, doped indium oxide, doped cadmium oxide, various other doped variants derived therefrom, amorphous silicon, crystalline silicon, or the like. The first portion 122 and the second portion 124 may include a same material, while the third portion 126 includes a material different from those of the first portion 122 and the second portion 124. In other embodiments, the first portion 122, the second portion 124 and the third portion 126 may include same materials but in different compositions. For example but not limited thereto, each of the first portion 122, the second portion 124 and the third portion 126 may include InO, but an In concentration in the first portion 122 and an In concentration in the second portion 124 are greater than an In concentration in the third portion 126. In such embodiments, the first portion 122 and the second portion 124 may be referred to as In-rich portions, while the third portion 126 is referred to as an In-poor portion.

Referring to FIG. 2, in some embodiments, the first portion 122, the second portion 124 and the third portion 126 of the semiconductor device 100′ include a same material.

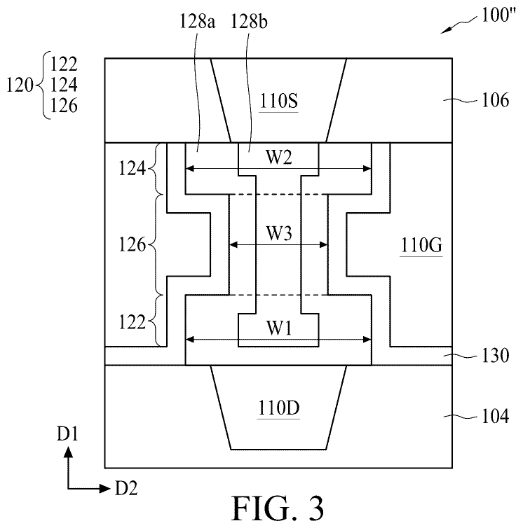

Referring to FIG. 3, in some embodiments, each of the first portion 122, the second portion 124 and the third portion 126 includes a first channel layer 128a and a second channel layer 128b. The first channel layer 128a is disposed between the gate dielectric layer 130 and the second channel layer 128b. In other words, the second channel layer 128b is separated from the gate dielectric layer 130 and the gate structure 110G by the first channel layer 128a. In some embodiments, the first channel layer 128a forms sidewalls and a bottom of the channel pillar 120. In such embodiments, the first channel layer 128a is in contact with the gate dielectric layer 130. As shown in FIG. 3, the first channel layer 128a of the first portion 122 is coupled to the drain structure 110D, and the second channel layer 128b of the second portion 124 is coupled to the source structure 110S. In some embodiments, portions of the first channel layer 128a may be coupled to the source structure 110S, as shown in FIG. 3, but the disclosure is not limited thereto. Additionally, the second channel layer 128b of the third portion 126 is coupled to the second channel layer 128b of the first portion 122 and the second channel layer 128b of the second portion 124.

The first channel layer 128a and the second channel layer 128b may include a same material such as, for example but not limited thereto, an oxide semiconductor material (such as indium gallium zinc oxide (InGaZnO, IGZO), tungsten-doped indium oxide (InWO), indium zinc oxide (InZnO), indium tin oxide (InSnO), indium tungsten oxide (InWO), gallium oxide (GaOx), indium oxide (InOx) and the like), doped zinc oxide, doped indium oxide, doped cadmium oxide, various other doped variants derived therefrom, amorphous silicon, crystalline silicon, or the like. However, a dopant concentration of the first channel layer 128a is different from a dopant concentration of the second channel layer 128b. For example, the dopant concentration of the first channel layer 128a is greater than the dopant concentration of the second channel layer 128b. The greater dopant concentration of the first channel layer 128a improves gate control of the semiconductor device 100″.

Referring to FIGS. 4 and 5, as mentioned above, the semiconductor devices 100, 100′ or 100″ may be disposed in the BEOL interconnect structure 102. Further, the semiconductor device 100 is disposed in the dielectric structure 104 and 106. In some embodiments, each of the dielectric structures 104 and 106 may include multiple insulating layers (i.e., an IMD layer, IMDn) of the BEOL interconnect structure 102. In some embodiments, the dielectric structures 104 and 106 may include a first region 108a, where the semiconductor device 100, 100′ or 100″ is disposed, and a second region 108b, where metallization layers 140 and 142 (i.e., the Nth metallization layer Mₙ and the (N+1)th metallization layer Mₙ₊₁) are disposed. Further, a connecting via 144 (i.e., the Nth connecting via Vₙ) is disposed in the dielectric structures 104 and 106 in the second region 108b, and electrically connects the metallization layers 140 and 142 to each other. In some embodiments, the semiconductor device 100, 100′ or 100″ is electrically connected to metallization layers 150 and 152 disposed in the first region 108a. Referring to FIG. 4, in some embodiments, the metallization layers 140 and 150 are disposed in a same level (i.e., a level accommodating the Nth metallization layer Mₙ), and the metallization layers 142 and 152 are disposed in a same level (i.e., a level accommodating the (N+1)th metallization layer Mₙ₊₁).

Referring to FIG. 5, in other embodiments, more metallization layers may be disposed in the second region 108b. For example, metallization layers 140, 142 and 146 (i.e., the (N−1)th metallization layer Mₙ₋₁, the Nth metallization layer Mₙ and the (N+1)th metallization layer Mₙ₊₁) are disposed. Further, connecting vias 144 and 148 (i.e., the (N−1)th and Nth connecting vias Vₙ₋₁ and Vₙ) is disposed in the dielectric structures 104 and 106 in the second region 108b, and electrically connect the metallization layers 140, 142 and 146. In some embodiments, the semiconductor device 100, 100′ or 100″ is electrically connected to metallization layers 150 and 152. Referring to FIG. 5, in some embodiments, the metallization layers 140 and 150 are disposed in a same level (i.e., a level accommodating the (N−1)th metallization layer Mₙ₋₁), and the metallization layers 146 and 152 are disposed in a same level (i.e., a level accommodating the (N+1)th metallization layer Mₙ₊₁).

It should be noted that the semiconductor devices 100, 100′ and 100′′ can be disposed in various levels in the BEOL interconnect structure 102. As mentioned above, the semiconductor devices 100, 100′ and 100″ can be disposed in a level between two metallization layers (i.e., the metallization layers 140 and 142), as shown in FIG. 4. In other embodiments, the semiconductor devices 100, 100′ and 100″ can be disposed in a level between three metallization layers (i.e., the metallization layers 140, 142 and 146), and can form a channel length greater than that formed by the semiconductor devices disposed in the level between two metallization layers. It is concluded that the semiconductor devices 100, 100′ and 100″ can be disposed in various levels according to different product designs in order to obtain different channel lengths.

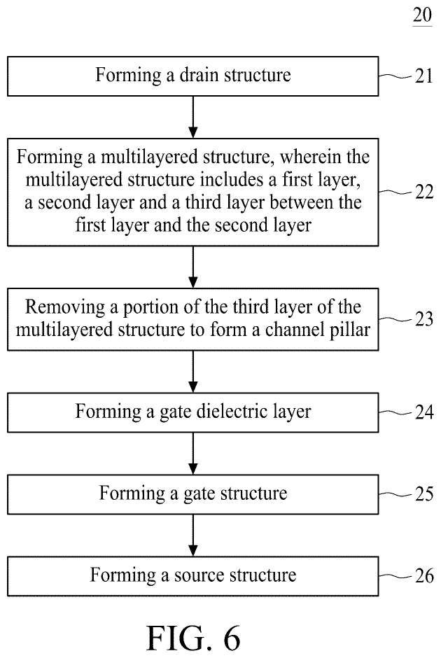

FIG. 6 is a flowchart representing a method for forming a semiconductor device 20 in accordance with aspects of the present disclosure. The method 20 includes a number of operations (21, 22, 23, 24, 25 and 26). The method 20 is further described according to one or more embodiments. It should be noted that the operations of the method 20 may be rearranged or otherwise modified within the scope of the various aspects. It should be further noted that additional processes may be provided before, during, and after the method 20, and that some other processes may be only briefly described herein. Thus, other implementations are possible within the scope of the various aspects described herein.

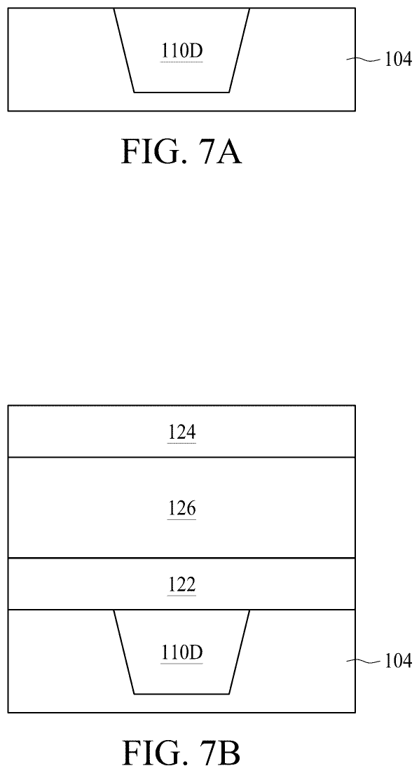

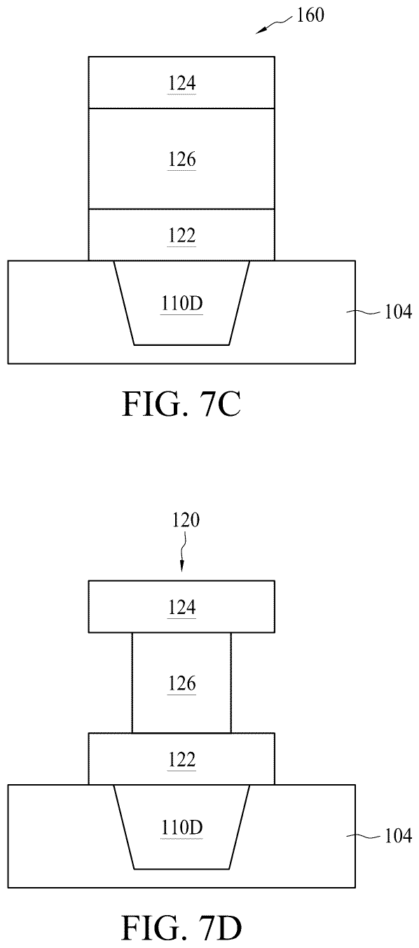

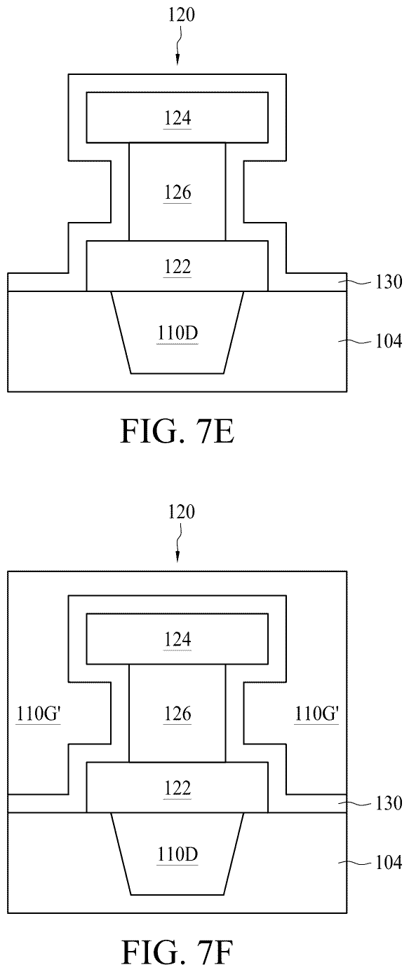

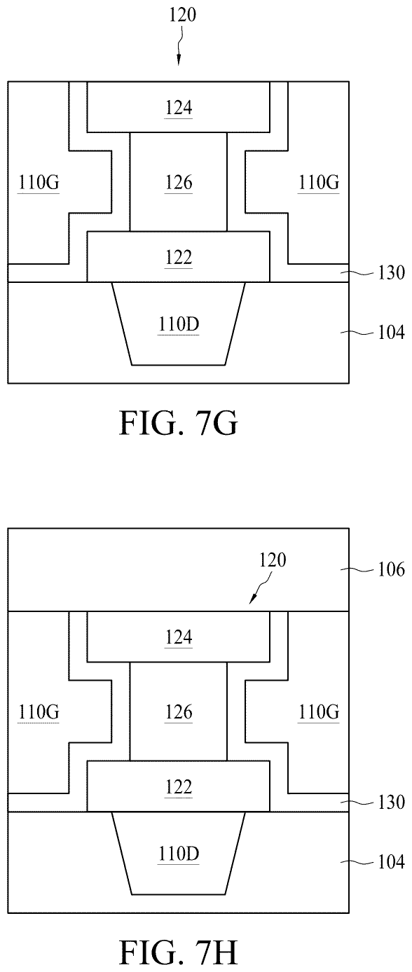

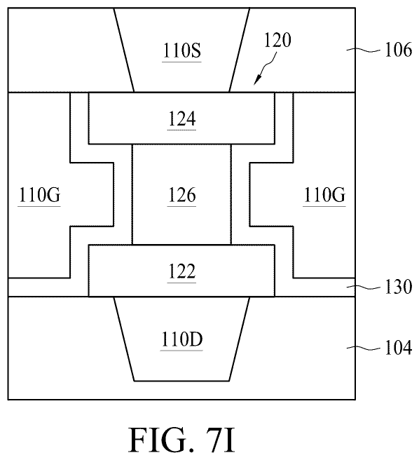

In some embodiments, a semiconductor device 100 may be formed by the method 20. FIGS. 7A to 7I are schematic drawings of the semiconductor device 100 at various fabrication stages constructed according to aspects of the present disclosure in one or more embodiments.

Referring to FIG. 7A, in some embodiments, in operation 21, a drain structure 110D is formed. In some embodiments, operation 21 includes further operations. For example, a dielectric structure 104 may be formed over a substrate (not shown), wherein the substrate may be referred to as a supporting structure. The substrate may include FEOL devices, MEOL elements, and a BEOL interconnect structure 102. In some embodiments, the substrate may be a part of the BEOL interconnect structure 102 (as shown in FIGS. 4 and 5). In some embodiments, the dielectric structure 104 may be a part of an inter-metal dielectric (IMD) of the BEOL interconnect structure 102. In some embodiments, the dielectric structure 104 may be a single-layered structure. In other embodiments, the dielectric structure 104 may be a multi-layered structure. The dielectric layer 104 includes silicon oxide, silicon nitride, silicon oxynitride, or the like, which may be deposited by chemical vapor deposition (CVD), physical vapor deposition (PVD), atomic layer deposition (ALD), plasma-enhanced CVD (PECVD), or the like.

Still referring to FIG. 7A, in some embodiments, the drain structure 110D is formed in the dielectric structure 104. In some embodiments, a patterned hard mask (not shown) is formed over the dielectric structure 104. The patterned hard mask may include at least an opening exposing a portion of the dielectric structure 104. For example, the opening corresponds to a shape of the drain structure 110D formed in subsequent steps. After the formation of the patterned hard mask, an etching process is performed to remove the exposed portion of the dielectric structure 104, thereby forming at least a recess (not shown). Subsequently, a conductive material is deposited to fill the recess. In some embodiments, a barrier layer (not shown) may be formed prior to the deposition of the conductive material. The conductive material may be similar to materials of the drain structure described above; therefore, repeated descriptions are omitted. A planarization is performed to remove superfluous material, thereby forming the drain structure 110D.

Referring to FIG. 7B, in operation 22, a multilayered structure 160 is formed over the substrate. In some embodiments, operation 22 include further operations. For example, a layer 122, a layer 126 and a layer 124 are sequentially deposited over the substrate, the dielectric structure 104 and the drain structure 110D. Each of the layers 122, 126 and 124 may be deposited by CVD, PVD, ALD, PECVD, or the like. Materials for forming the layers 122, 126, and 124 may be similar to materials of the portions 122, 126 and 124 described above; therefore, repeated descriptions are omitted. In some embodiments, the layers 122 and 124 may include a same material, while the layer 126 includes a material different from that of the layers 122 and 124. In other embodiments, the layers 122, 124 and 126 may include same materials but in different compositions. For example but not limited thereto, each of the layers 122, 124 and 126 may include InO, but an In concentration in the layer 122 and an In concentration in the layer 124 are greater than an In concentration in the layer 126. In such embodiments, the layers 122 and 124 may be referred to as In-rich layers, while the layer 126 is referred to as an In-poor layer.

Referring to FIG. 7C, in some embodiments, the layers 124, 126 and 122 are patterned to form the multilayered structure 160 over the substrate, the dielectric structure 104 and the drain structure 110D. In some embodiments, a patterned hard mask (not shown) is formed over the layer 124. The patterned hard mask may cover a portion of the layers 124, 126 and 122. For example, the portion may correspond to a shape of the multilayered structure 160 formed in subsequent steps. After the formation of the patterned hard mask, an etching process, such as a dry etching process, is performed to remove exposed portions of the layers 124, 126 and 122, thereby forming the multilayered structure 160. As shown in FIG. 7C, the multilayered structure 160 overlaps the drain structure 110D. Further, a width of the multilayered structure 160 is greater than a width of the drain structure 110D.

Referring to FIG. 7D, in operation 23, a portion of the layer 126 of the multilayered structure 160 is removed to form a channel pillar 120. In some embodiments, a lateral etching process may be performed to remove the portion of the layer 126. Further, a lateral wet etching process may be used. In such embodiments, an etchant having a high etching selectivity ratio of the In-poor layer 126 to the In-rich layers 122 and 124 may be used in the lateral etching. Accordingly, the portion of the layer 126 is laterally removed. As shown in FIG. 7D, a width of the layer 126 is thereby reduced to be less than a width of the layer 122, and less than a width of the layer 124. In some embodiments, the channel pillar 120 can be referred to as a bone-shaped channel pillar. Further, the channel pillar 120 overlaps and is coupled to the drain

### Structure 110d.

Referring to FIG. 7E, in some embodiments, in operation 24, a gate dielectric layer 130 is formed over the substrate, the dielectric structure 104 and the channel pillar 120. A material of the gate dielectric layer 130 may be similar to materials of the gate dielectric layers described above, and repeated descriptions are omitted. In some embodiments, the gate dielectric layer 130 may be formed using one or more deposition processes (e.g., ALD, CVD, PVD, PECVD, or the like). As shown in FIG. 7E, the gate dielectric layer 130 covers sidewalls of the channel pillar 120, a top surface of the channel pillar 120, and a surface of the dielectric structure 104.

In some embodiments, in operation 25, a gate structure 110G surrounding the gate dielectric layer 130 and the sidewalls of the channel pillar 120 is formed. A material of the gate structure 110G may be similar to materials of the gate structures described above; therefore, repeated descriptions are omitted. Operation 25 may include further operations. For example, referring to FIG. 7F, a gate material layer 110G′ may be formed over the gate dielectric layer 130. In some embodiments, the gate material layer 110G′ may be formed using one or more depositions (e.g., ALD, CVD, PECVD, or the like). A planarization operation, such as a chemical mechanical polishing (CMP) operation, is subsequently performed to remove portions of the gate material layer 110G′ and the portion of the gate dielectric layer 130 to form the gate structure 110G. As shown in FIG. 7G, the top surface of the channel pillar 120 (i.e., a top surface of the layer 124) is exposed. Further, a top surface of the gate structure 110G, the top surface of the channel pillar 120 and a topmost portion of the gate dielectric layer 130 are aligned (i.e., coplanar) with each other.

In operation 26, a source structure 110S is formed after the formation of the gate structure 110G. In some embodiments, operation 26 includes further operations. For example, referring to FIG. 7H, a dielectric structure 106 may be formed over the channel pillar 120 and the gate structure 110G. In some embodiments, the dielectric structure 106 may include materials same as materials of the IMD in the BEOL interconnect structure 102, but the disclosure is not limited thereto. In some embodiments, the dielectric structure 106 may be a single-layered structure. In other embodiments, the dielectric structure 106 may be a multi-layered structure.

Referring to FIG. 7I, in some embodiments, a patterned hard mask (not shown) is formed over the dielectric structure 106. The patterned hard mask may include at least an opening exposing a portion of the dielectric structure 106. For example, the opening corresponds to a shape of the source structure 110S formed in subsequent steps. After the formation of the patterned hard mask, an etching process is performed to remove the exposed portion of the dielectric structure 106, thereby forming at least a recess (not shown). Subsequently, a conductive material is deposited to fill the recess. In some embodiments, a barrier layer (not shown) may be formed prior to the deposition of the conductive material. The conductive material may be similar to materials of the source structure described above; therefore, repeated descriptions are omitted. A planarization is performed to remove superfluous material, thereby forming the source structure 110S. As shown in FIG. 7I, the source structure 110S is coupled to the channel pillar 120 (i.e., the layer 124 of the channel pillar 120).

Accordingly, the semiconductor device 100 having a bone-shaped channel pillar 120 is obtained. As mentioned above, the width of the layer 126 (also referred to as a third portion) of the channel pillar 120 is less than the width of the layer 122 (also referred to as a first portion) of the channel pillar 120, and less than the width of the layer 124 (also referred to as a second portion) of the channel pillar 124. In some embodiments, by modifying operations for patterning the layers 122, 124 and 126 to form the multilayered structure 160, the widths of the layers 122 and 124 can be increased to mitigate a gate-to-drain short issue. Further, by modifying operations for removing the portion of the layer 126, the width of layer 126 can be reduced to improve channel control ability.

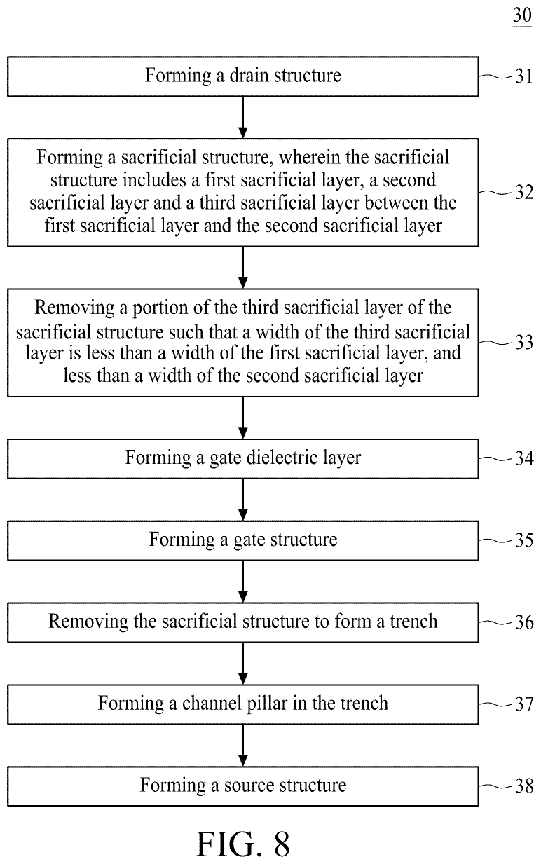

FIG. 8 is a flowchart representing a method for forming a semiconductor device 30 in accordance with aspects of the present disclosure. The method 30 includes a number of operations (31, 32, 33, 34, 35, 36, 37 and 38). The method 30 is further described according to one or more embodiments. It should be noted that the operations of the method 30 may be rearranged or otherwise modified within the scope of the various aspects. It should be further noted that additional processes may be provided before, during, and after the method 30, and that some other processes may be only briefly described herein. Thus, other implementations are possible within the scope of the various aspects described herein.

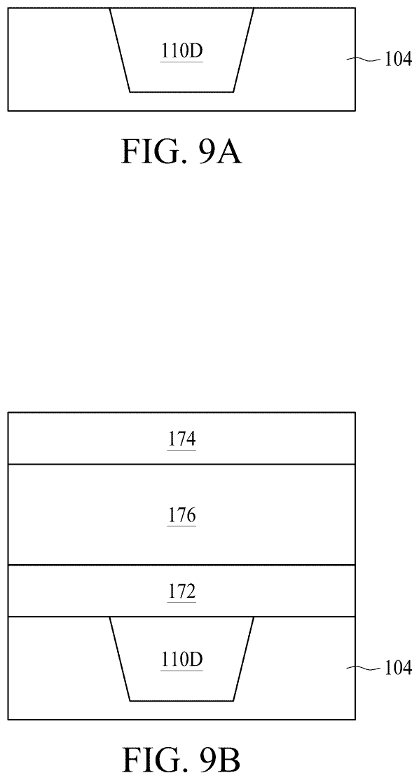

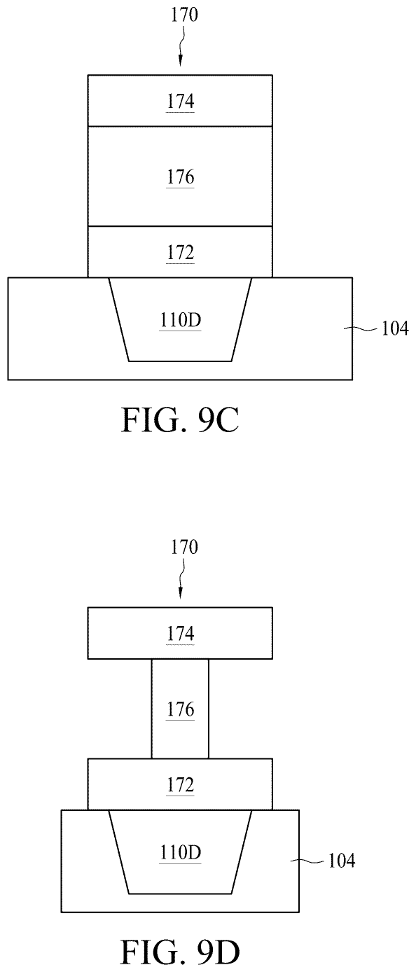

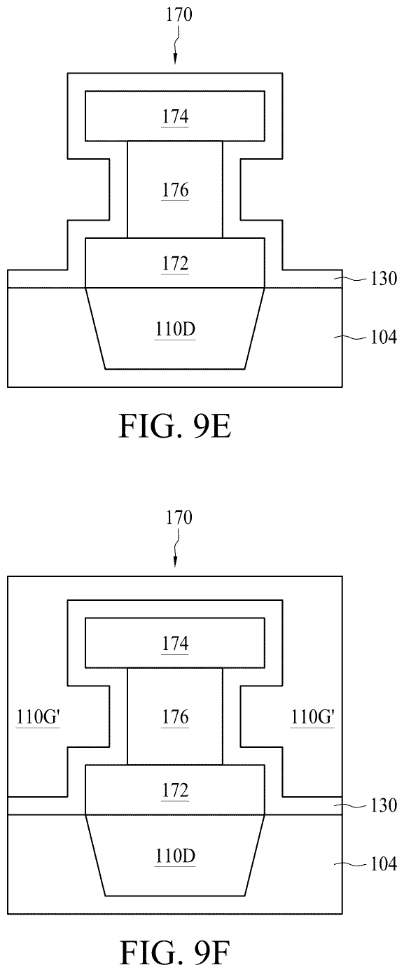

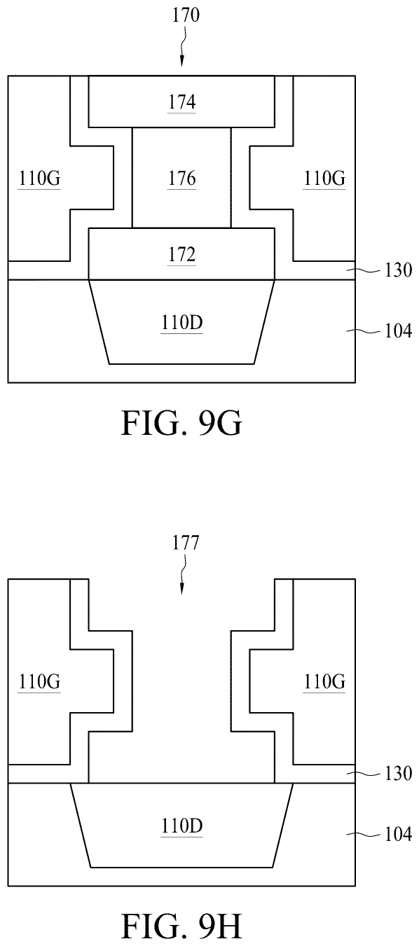

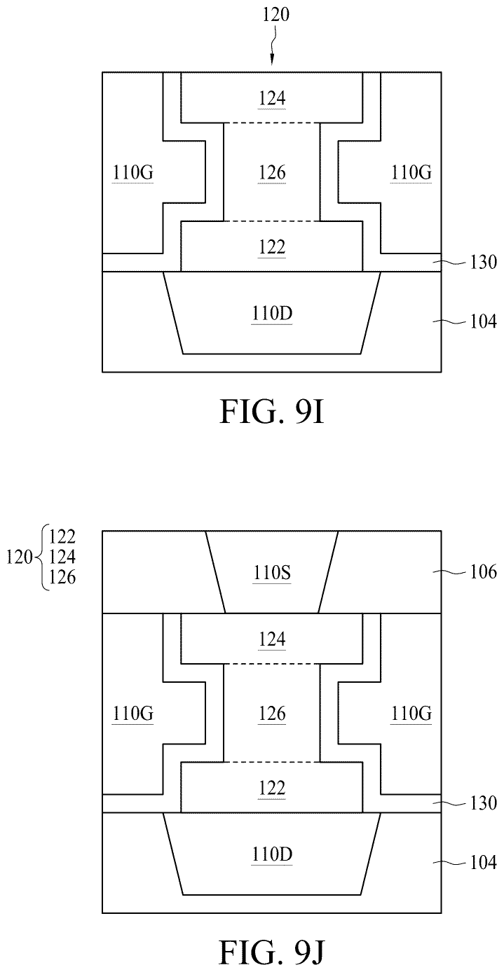

In some embodiments, a semiconductor device 100′ may be formed by the method 30. FIGS. 9A to 9J are schematic drawings of the semiconductor device 100′ at various fabrication stages constructed according to aspects of the present disclosure in one or more embodiments.

Referring to FIG. 9A, in some embodiments, in operation 31, a drain structure 110D is formed. In some embodiments, details of operation 31 may be similar to those of operation 21; therefore, repeated descriptions are omitted for brevity.

In operation 32, a sacrificial structure 170 is formed over the substrate. In some embodiments, operation 32 include further operations. For example, referring to FIG. 9B, sacrificial layers 172, 176 and 174 are sequentially deposited over the substrate, the dielectric structure 104 and the drain structure 110D. Each of the sacrificial layers 172, 176 and 174 may be deposited by CVD, PVD, ALD, PECVD, or the like. In some embodiments, the sacrificial layers 172 and 174 may include a same material, while the sacrificial layer 176 includes a material different from that of the sacrificial layers 172 and 174. For example, the sacrificial layers 172 and 174 may include silicon oxide, while the sacrificial layer 176 includes aluminum oxide. In other embodiments, the sacrificial layers 172, 174 and 176 may include a same material but formed by different operations. For example, the sacrificial layers 172 and 174 may include silicon oxide formed by an ALD, while the sacrificial layer 176 includes silicon oxide formed by CVD.

Referring to FIG. 9C, in some embodiments, the sacrificial layers 174, 176 and 172 are patterned to form the sacrificial structure 170 over the substrate, the dielectric structure 104 and the drain structure 110D. In some embodiments, a patterned hard mask (not shown) is formed over the sacrificial layer 174. The patterned hard mask may cover a portion of the sacrificial layers 174, 176 and 172. For example, the portion corresponds to a shape of the sacrificial structure 170 formed in subsequent steps. After the formation of the patterned hard mask, an etching process, such as a dry etching process, is performed to remove exposed portions of the sacrificial layers 174, 176 and 172, thereby forming the sacrificial structure 170. As shown in FIG. 9C, the sacrificial structure 170 overlaps the drain structure 110D. Further, a width of the sacrificial structure 170 is greater than a width of the drain structure 110D.

Referring to FIG. 9D, in operation 33, a portion of the sacrificial layer 176 of the sacrificial structure 170 is removed. In some embodiments, a lateral etching process may be performed to remove the portion of the sacrificial layer 176. Further, a lateral wet etching process may be used. In such embodiments, an etchant having a high etching selectivity ratio of the sacrificial layer 176 to the sacrificial layers 172 and 174 may be used in the lateral etching. Accordingly, the portion of the sacrificial layer 176 is laterally removed. As shown in FIG. 9D, a width of the sacrificial layer 176 is thereby reduced to less than a width of the sacrificial layer 172 and less than a width of the sacrificial layer 174. In some embodiments, the sacrificial structure 170 can be said to have a bone-shaped configuration. Further, the sacrificial structure 170 overlaps the drain structure 110D.

Referring to FIG. 9E, in some embodiments, in operation 34, a gate dielectric layer 130 is formed over the substrate, the dielectric structure 104 and the sacrificial structure 170. A material of the gate dielectric layer 130 may be similar to materials of the gate dielectric layers described above, and repeated descriptions are omitted. In some embodiments, the gate dielectric layer 130 may be formed using one or more deposition processes (e.g., ALD, CVD, PVD, PECVD, or the like). As shown in FIG. 9E, the gate dielectric layer 130 covers sidewalls of the sacrificial structure 170, a top surface of the sacrificial structure 170, and a surface of the dielectric structure 104.

In some embodiments, in operation 35, a gate structure 110G is formed. The gate structure 110G surrounds the gate dielectric layer 130 and the sidewalls of the sacrificial structure 170. A material of the gate structure 110G may be similar to materials of the gate structures described above; therefore, repeated descriptions are omitted. Operation 35 may include further operations. For example, referring to FIG. 9F, a gate material layer 110G′ may be formed over the gate dielectric layer 130. In some embodiments, the gate material layer 110G′ may be formed using one or more depositions (e.g., ALD, CVD, PECVD, or the like). Referring to FIG. 9G, a planarization operation, such as a CMP operation, is performed to remove portions of the gate material layer 110G′ and a portion of the gate dielectric layer 130 to form the gate structure 110G. As shown in FIG. 9G, the top surface of the sacrificial structure 170 (i.e., a top surface of the layer 174) is exposed. Further, a top surface of the gate structure 110G, the top surface of the sacrificial structure 170 and a topmost portion of the gate dielectric layer 130 are aligned (i.e., coplanar) with each other.

Referring to FIG. 9H, in operation 36, the sacrificial structure 170 is removed to form a trench 177. As shown in FIG. 9H, the gate dielectric layer 130 is exposed through sidewalls of the trench 177. Further, the drain structure 110D is exposed through a bottom of the trench 177.

Referring to FIG. 9I, in operation 37, a channel pillar 120 is formed in the trench 177. A material of the channel pillar 120 may be similar to materials of the channel pillar described above; therefore, repeated descriptions are omitted. Operation 37 may include further operations. For example, the trench 177 is filled with a material (i.e., an oxide semiconductor material). In some embodiments, such material may be formed using one or more depositions (e.g., ALD, CVD, PECVD, or the like). A planarization operation, such as a CMP operation, is subsequently performed to remove portions of the material to form the channel pillar 120. As shown in FIG. 9I, a top surface of the channel pillar 120, the top surface of the gate structure 110G and the topmost portion of the gate dielectric layer 130 are aligned (i.e., coplanar) with each other.

Still referring to FIG. 9I, in such embodiments, the channel pillar 120 has a first portion 122, a second portion 124 and a third portion 126 between the first portion 122 and the second portion 124. All of the first, second and third portions 122, 124 and 126 include a same material. Further, a width of the first portion 122 and a width of the second portion 124 are greater than a width of the third portion 126.

In operation 38, a source structure 110S is formed after the formation of the channel pillar 120. In some embodiments, operation 38 includes further operations. For example, referring to FIG. 9J, a dielectric structure 106 may be formed over the channel pillar 120 and the gate structure 110G. In some embodiments, the dielectric structure 106 may include materials same as materials of the IMD in the BEOL interconnect structure 102, but the disclosure is not limited thereto. In some embodiments, the dielectric structure 106 may be a single-layered structure. In other embodiments, the dielectric structure 106 may be a multi-layered structure. A patterned hard mask (not shown) is formed over the dielectric structure 106. The patterned hard mask may include at least an opening exposing a portion of the dielectric structure 106. For example, the opening corresponds to a shape of the source structure 110S formed in subsequent steps. After the formation of the patterned hard mask, an etching process is performed to remove the exposed portion of the dielectric structure 106, thereby forming at least a recess (not shown). Subsequently, a conductive material is deposited to fill the recess. In some embodiments, a barrier layer (not shown) may be formed prior to the deposition of the conductive material. The conductive material may be similar to materials of the source structure described above; therefore, repeated descriptions are omitted. A planarization is performed to remove superfluous material, thereby forming the source structure 110S. As shown in FIG. 9J, the source structure 110S is coupled to the channel pillar 120.

Accordingly, the semiconductor device 100′ having a bone-shaped channel pillar 120 is obtained. As mentioned above, the channel pillar 120 includes the first portion 122, the second portion 124, and the third portion 126 all having the same material. The width of the third portion 126 is less than the width of the first portion 122, and less than the width of the second portion 124. In some embodiments, by modifying operations for forming the sacrificial structure 170 (i.e., patterning the sacrificial layers 172, 176 and 174), the widths of the first and second portions 122 and 124 can be increased to mitigate a gate-to-drain short issue. Further, by modifying operations for removing the portion of the sacrificial layer 176, the width of the third portion 126 can be reduced to mitigate a channel void issue, further improving a gate control ability.

In some embodiments, the method 30 may be performed to form the semiconductor device 100″. For example, in operation 31, a drain structure 140D may be formed. In operation 32, a sacrificial structure 170 having the sacrificial layers 172, 174 and 176 is formed. In operation 33, a portion of the sacrificial structure 170 is removed such that a width of the sacrificial layer 176 is less than a width of the sacrificial layer 172, and less than a width of the sacrificial layer 174. In operation 34, a gate dielectric layer 130 is formed. In operation 35, a gate structure 110G is formed. In operation 36, the sacrificial structure 170 is removed to form a trench 177.

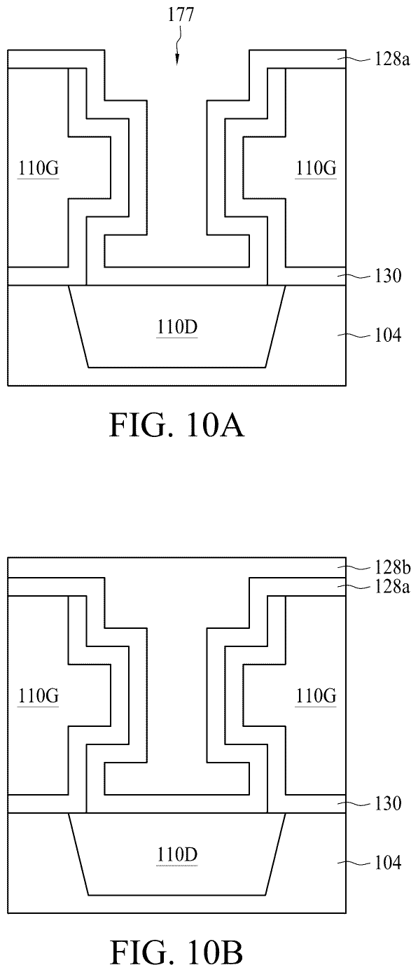

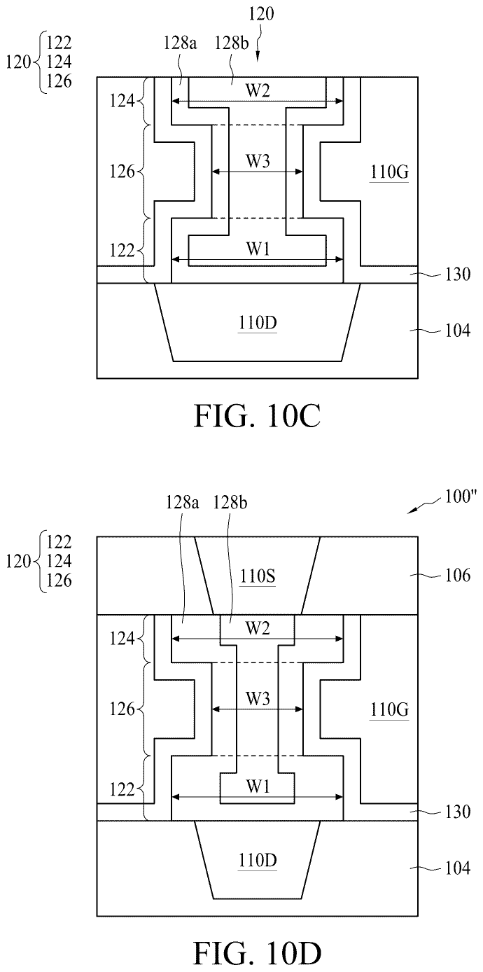

In operation 37, a channel pillar 120 is formed in the trench 177. In some embodiments, operation 37 includes further operations. For example, as shown in FIG. 10A, a first channel layer 128a is formed in the trench 177. In some embodiments, the first channel layer 128a is conformally formed in the trench 177. Therefore, the first channel layer 128a may cover a bottom and sidewalls of the trench 177. In some embodiments, the first channel layer 128a is coupled to the drain structure 110D that is exposed through the bottom of the trench 177.

Referring to FIG. 10B, the trench 177 is then filled with a second channel layer 128b. The first channel layer 128a and the second channel layer 128b may include a same material such as, for example but not limited thereto, oxide semiconductor material (such as indium gallium zinc oxide (InGaZnO, IGZO), tungsten-doped indium oxide (InWO), indium zinc oxide (InZnO), indium tin oxide (InSnO), indium tungsten oxide (InWO), gallium oxide (GaOx), indium oxide (InOx) and the like), doped zinc oxide, doped indium oxide, doped cadmium oxide, various other doped variants derived therefrom, amorphous silicon, crystalline silicon, or the like. However, a dopant concentration of the first channel layer 128a is different from a dopant concentration of the second channel layer 128b. For example, the dopant concentration of the first channel layer 128a is greater than the dopant concentration of the second channel layer 128b. The first channel layer 128a having the greater dopant concentration improves gate control of the semiconductor device 100″.

Referring to FIG. 10C, a planarization operation such as a CMP operation is performed to remove superfluous portions of the second channel layer 128b to form the channel pillar 120. In some embodiments, a top surface of the second channel layer 128b may be aligned (i.e., coplanar) with a topmost surface of the first channel layer 128a and the top surface of the gate structure 110G, as shown in FIG. 10C. In some embodiments, the second channel layer 128b may have a bone-shaped configuration, but the disclosure is not limited thereto. Further, the channel pillar 120 that includes the first and second channel layers 128a and 128b obtains a bone-shaped configuration. As shown in FIG. 10C, the channel pillar 120 includes a first portion 122, a second portion 124 and a third portion 126 between the first portion 122 and the second portion 124. Further, a width of the third portion 126 is less than a width of the first portion 122, and less than a width of the second portion 124.

Referring to FIG. 10D, in operation 38, a source structure 110S is formed after the forming of the channel pillar 120. Accordingly, the semiconductor device 100″ having a bone-shaped channel pillar 120 is obtained.

In summary, the present disclosure provides a semiconductor device and a method for forming the same. In some embodiments, the semiconductor device includes a bone-shaped channel pillar that helps to reduce both the gate-to-drain short issue and the channel void issue by: (1) having wide portions at two opposite ends proximal to the source structure and the drain structure, thereby mitigating the gate-to-drain issue; and (2) having a narrow portion between the two wide portions, thereby improving a gap-filling result and gate control ability, and mitigating the channel void issue.

In some embodiments, a semiconductor device is provided. The semiconductor device includes a source structure and a drain structure arranged in a first direction, a channel pillar disposed between the source structure and the drain structure in the first direction, a gate structure surrounding the channel pillar in a second direction different from the first direction, and a gate dielectric layer between the gate structure and the channel pillar. The channel pillar includes a first portion coupled to the drain structure, a second portion coupled to the source structure, and a third portion between the first portion and the second portion. A width of the third portion is less than a width of the first portion, and less than a width of the second portion.

In some embodiments, a method for forming a semiconductor device is provided. The method includes following operations. A multilayered structure is formed over a substrate. The multilayered structure includes a first layer, a second layer and a third layer between the first layer and the second layer. A portion of the third layer is removed to form a channel pillar. A gate dielectric layer surrounding sidewalls of the channel pillar is formed. A gate structure surrounding the gate dielectric layer and the sidewalls of the channel pillar is formed. A width of the third layer of the channel pillar is less than a width of the first layer of the channel pillar, and less than a width of the second layer of the channel pillar.

In some embodiments, a method for forming a semiconductor device is provided. The method includes following operations. A sacrificial structure is formed over a substrate. The sacrificial structure includes a first sacrificial layer, a second sacrificial layer and a third sacrificial layer between the first sacrificial layer and the second sacrificial layer. A portion of the third sacrificial layer is removed such that a width of the third sacrificial layer is less than a width of the first sacrificial layer, and less than a width of the second sacrificial layer. A gate dielectric layer surrounding sidewalls of the sacrificial structure is formed. A gate structure surrounding the gate dielectric layer and the sidewalls of the sacrificial structure is formed. The sacrificial structure is removed to form a trench. A channel pillar is formed in the trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a source structure and a drain structure arranged in a first direction;
a channel pillar disposed between the source structure and the drain structure in the first direction;
a gate structure surrounding the channel pillar in a second direction different from the first direction; and
a gate dielectric layer between the gate structure and the channel pillar,
wherein the channel pillar comprises a first portion coupled to the drain structure, a second portion coupled to the source structure, and a third portion disposed between the first portion and the second portion, and
wherein a width of the third portion is less than a width of the first portion, and less than a width of the second portion.

2. The semiconductor device of claim 1, wherein each of the first portion, the second portion and the third portion comprises a material, and a concentration of the material in the first portion and a concentration of the material in the second portion are greater than a concentration of the material in the third portion.

3. The semiconductor device of claim 1, wherein the first portion, the second portion and the third portion comprise a same material.

4. The semiconductor device of claim 1, wherein each of the first portion, the second portion and the third portion comprises a first channel layer and a second channel layer.

5. The semiconductor device of claim 4, wherein the first channel layer of the first portion is coupled to the drain structure.

6. The semiconductor device of claim 4, wherein the second channel layer of the second portion is coupled to the source structure.

7. The semiconductor device of claim 4, wherein the second channel layer of the third portion is coupled to the second channel layer of the first portion and the second channel layer of the second portion.

8. The semiconductor device of claim 1, wherein the width of the first portion of the channel pillar is greater than a width of the drain structure.

9. The semiconductor device of claim 1, wherein the width of the second portion of the channel pillar is greater than a width of the source structure.

10. The semiconductor device of claim 1, wherein a thickness of the third portion is greater than a thickness of the first portion, and greater than a thickness of the second portion.

11. A method for forming a semiconductor device, comprising:
forming a multilayered structure over a substrate, wherein the multilayered structure comprises a first layer, a second layer and a third layer between the first layer and the second layer;
removing a portion of the third layer of the multilayered structure to form a channel pillar;
forming a gate dielectric layer surrounding sidewalls of the channel pillar; and
forming a gate structure surrounding the gate dielectric layer and the sidewalls of the channel pillar,
wherein a width of the third layer of the channel pillar is less than a width of the first layer of the channel pillar, and less than a width of the second layer of the channel pillar.

12. The method of claim 11, wherein each of the first layer, the second layer and the third layer comprises a material, and a concentration of the material in the first layer and a concentration of the material in the second layer are greater than a concentration of the material in the third layer.

13. The method of claim 11, further comprising forming a drain structure prior to the forming of the multilayered structure, wherein the channel pillar is coupled to the drain structure.

14. The method of claim 11, further comprising forming a source structure coupled to the channel pillar after the forming of the gate structure.

15. A method for forming a semiconductor device, comprising:
forming a sacrificial structure over a substrate, wherein the sacrificial structure comprises a first sacrificial layer, a second sacrificial layer and a third sacrificial layer between the first sacrificial layer and the second sacrificial layer;
removing a portion of the third sacrificial layer of the sacrificial structure such that a width of the third sacrificial layer is less than a width of the first sacrificial layer, and less than a width of the second sacrificial layer;
forming a gate dielectric layer surrounding sidewalls of the sacrificial structure;
forming a gate structure surrounding the gate dielectric layer and the sidewalls of the sacrificial structure;
removing the sacrificial structure to form a trench; and
forming a channel pillar in the trench.

16. The method of claim 15, wherein the first layer and the second layer comprise a first material, and the third layer comprises a second material different from the first material.

17. The method of claim 15, wherein the gate dielectric layer is exposed through sidewalls of the trench.

18. The method of claim 15, wherein the forming of the channel pillar further comprises:
forming a first channel layer covering a bottom and sidewalls of the trench; and
filling the trench with a second channel layer.

19. The method of claim 15, further comprising forming a drain structure prior to the forming of the sacrificial structure, wherein the channel pillar is coupled to the drain structure.

20. The method of claim 15, further comprising forming a source structure coupled to the channel pillar after the forming of the channel pillar.
